(19) United States
(12) Patent Application Publication
(10) Pub. No.: US 2007/0022949 A1
(43) Pub. Date: Feb. 1, 2007

(54) High-pressure processing apparatus

(75) Inventor: Kimitsugu Saito, Kyoto (JP)

Correspondence Address: OSTROLENK FABER GERB & SOFFEN, 1180 AVENUE OF THE AMERICAS, NEW YORK, NY, 100368403, US

(73) Assignee: Dainippon Screen Mfg. Co., Ltd.

(21) Appl. No.: 11/471,874

(22) Filed: Jun. 20, 2006

(30) Foreign Application Priority Data
Jul. 29, 2005 (JP) 2005-220702

(51) Int. Cl. B05C 13/02; C23C 14/00

(52) U.S. Cl. 118/52; 118/50; 118/612

(57) ABSTRACT

Processing fluid is vertically incident to a surface S1 of a rotation substrate W through a delivery path provided on a pressure vessel. The curtain of processing fluid has a width longer than a diameter of the substrate. Therefore, a cleaning process is execute onto the whole surface of the substrate by the processing fluid.

### CROSS REFERENCE TO RELATED APPLICATION

The disclosure of Japanese Patent Application No. 2005-220702 filed Jul. 29, 2005 including specification, drawings and claims is incorporated herein by reference in its entirety.

### BACKGROUND OF THE INVENTION

1. Field of the Invention

The present invention relates to a high-pressure processing apparatus. The apparatus cause a processing fluid to come into contact with a surface of an object-to-be-processed such as a substrate, thereby performing a predetermined surface treatment (e.g. developing, cleaning, drying or the like) for the surface of the object-to-be-processed. The processing fluid includes a high-pressure fluid or a mixture of a high-pressure fluid and a chemical agent.

2. Description of the Related Art

Conventionally proposed is a technique of a high-pressure cleaning process which sets up a substrate within a pressure vessel and uses a supercritical fluid (hereinafter referred to as “SCF”) having low viscosity and high diffusion property. Followings are known as an apparatus to supply the supercritical fluid to the substrate. For example, the apparatus described in JP-A-2003-71394 horizontally holds a substrate in a chamber. Also a SCF supply line is set on one edge side of the substrate and a SCF discharge line is set on the other edge side of the substrate. The SCF (processing fluid) with chemical agent is blown off from the SCF supply line toward the SCF discharge line, so that the processing fluid flows onto a surface of the substrate in parallel to the surface and cleans the substrate. A document of JP-A-2005-1464573 describes an apparatus which drys a substrate by using SCF. In this apparatus, SCF is supplied to an upper central portion of the substrate that is held by the spin chuck and rotating inside the chamber. A document of JP-A-2004-1464573 describes an apparatus which disperses SCF and supplies the dispersed SCF to a substrate, to thereby execute cleaning process and drying process for the substrate. In this apparatus, a disc-like blockage plate, which has many distribution holes vertically passing through, is disposed so as to face to a surface of the substrate. The SCF is introduced from a fluid inlet port equipped to an upper part of the chamber. Then, the SCF is dispersed by the blockage plate and then supplied vertically toward the surface of the substrate through each distribution holes. By this, the cleaning process and drying process are applied to the substrate.

### SUMMARY OF THE INVENTION

It is well known that a flow of SCF on the surface of the substrate has a great influence on surface treatments process. Studies about the influence of the SCF flow in detail show existences of other factor. In other words, in addition to speed of the SCF flow, a direction of the SCF flow on the surface of the substrate is affector for the surface treatment process. It has also been found out from various experimental results that the flow perpendicular to the substrate accelerates the surface treatment process under the same speed of flow. Therefore, in consideration thereof, it is very important to improve a throughput as well as to satisfy uniformity of the processing for the surface of the substrate and replaceability of the SCF within the chamber.

However, the apparatus described in the JP-A-2003-71394 executes the surface treatment for the substrate with the SCF which flows in parallel to the surface of the substrate. Hence, the apparatus has problems of slowing the processing speed and decreasing the throughput.

Further, in the apparatus described in the JP-A-2004-186526, the SCF is vertically incidence only to a central portion (a top central portion) of the surface. Therefore, the central portion of the surface is under the priority treatment with the SCF, whereby the nonuniformity within the surface of the substrate increases. Specifically, the central portion of the surface is processed by the vertical SCF, whereas the edge portion of the surface is processed by the parallel SCF which spreads out by centrifugal force arising from the rotation of the substrate. As a result, it is hard to keep the uniformity of the surface treatment for the substrate.

Further, the apparatus described in the JP-A-2004-1464573 has the following problems although SCF is vertically incident to the substrate through the distribution holes provided on the disc-like blockage plate. That is, the blockage plate with a surface area of the substrate dimension or more is prepared and formed with many distribution holes. To blow off the SCF to the whole surface of the substrate from openings of the distribution holes, high work accuracy for the blockage plate is required. However, as a matter of fact, it is very difficult to shape into such disc-like (this includes the disc itself shape and the shape of the distribution holes and the setting place of the holes) with high accuracy. As a result, the speed of the SCF which is incidence to the surface of the substrate is nonuniform and the surface treatment for the substrate is nonuniform within the surface of the substrate. As the SCF introduced along a fluid inlet path is blew off from the distribution holes so as to be dispersed to all over the surface of the substrate, the speed of the SCF which is vertically incidence to the surface from each distribution hole is getting slow. As a result, the processing efficiency per dimension is decreased.

In addition, the blowing off the SCF to the whole surface of the substrate through the distribution holes occurs the following problems. The SCF (the central supply SCF), which is blew off onto the central portion of the surface, is supplied to the surface of the substrate. The supplied SCF flows along the surface and then discharged to outside of the substrate. However, the SCF is also blew off the edge portion of the surface surrounding the central portion of the substrate, so as to interfere with the distribution of the center supply SCF which flows from the central portion of the substrate to the outside of the substrate. As a result, this leads to a problem that the processed SCF is remain on the surface of the substrate.

The present invention aims at providing a high-pressure processing apparatus which cause a high-pressure fluid or a mixture of a high-pressure fluid and a chemical agent, as a processing fluid, to come into contact with a surface of an object-to-be-processed to perform a predetermined surface treatment for the surface of the object-to-be-processed while uniformity and throughput of the surface treatment can be enhanced.

The present invention is directed to a high-pressure processing apparatus which causes a high-pressure fluid or a mixture of a high-pressure fluid and a chemical agent, as a processing fluid, to come into contact with a surface of an object-to-be-processed, thereby performing a predetermined surface treatment for the surface of the object-to-be-processed. A high-pressure processing apparatus according to an aspect of the invention comprises: a supplier which supplies the processing fluid; a pressure vessel which has a processing chamber therein for performing the surface treatment; a holder which holds the object-to-be-processed inside the processing chamber; a rotating unit which rotates the object-to-be-processed held by the holder; a fluid delivery unit which has an opening and delivers the processing fluid, supplied from the supplier, vertically toward the object-to-be-processed of the substrate through the opening, so as to supply the processing fluid onto the surface of the object-to-be-processed, the opening being positioned on a rotation center of the object-to-be-processed and facing the surface of the object-to-be-processed; and a fluid discharge unit which discharges the processing fluid, supplied from the fluid delivery unit onto the surface of the object-to-be-processed, out of the pressure vessel, wherein the opening has a shape of a slit which elongates along a radial direction of the object-to-be-processed and has a slit length longer than a distance from the rotation center of the object-to-be-processed to an edge of the object-to-be-processed along the radial direction of the object-to-be-processed.

“A surface of an object-to-be-processed” in the present invention denotes a surface which should be subjected to a high-pressure process. In the case where the object-to-be-processed is one of various types of substrates such as a semiconductor wafer, a glass substrate for photomask, a glass substrate for liquid crystal display, a glass substrate for plasma display and an optical disk substrate, when it is necessary to carry out the high-pressure process for a first major surface which is formed with a circuit pattern and the like out of both major surfaces of the substrate, the first major surface corresponds to “a surface of an object-to-be-processed” in the present invention. On the other hand, when it is necessary to carry out the high-pressure process for a second major surface, the second major surface corresponds to “a surface of an object-to-be-processed” in the present invention. When it is necessary to carry out the high-pressure process for both major surfaces as in the case of a substrate populated on both major surfaces, each of the both major surfaces corresponds to “a surface of an object-to-be-processed” in the present invention, of course.

Cited as a representative example of a surface treatment in the present invention is a cleaning process for unsticking and removing a contaminant from the object-to-be-processed adhered with the contaminant such as a semiconductor substrate adhered with a resist. The object-to-be-processed is not limited to a semiconductor substrate, but denotes various types of base materials made of metal, plastic, ceramics or the like on which discontinuous or continuous layers made of materials different therefrom are formed or remain. The high-pressure processing apparatus and the high-pressure processing method of the present invention target not only the cleaning process but also all of processes for removing unnecessary materials from on the object-to-be-processed with the use of a high-pressure fluid and a chemical agent other than the high-pressure fluid (e.g. drying, developing or the like).

The high-pressure fluid used in the present invention is preferably carbon dioxide because of its safety, price and easiness of changing into a supercritical state. Other than carbon dioxide, water, ammonia, nitrogen monoxide, ethanol or the like may be used. The reasons why the high-pressure fluid is used are as follows. The high-pressure fluid has a high diffusion coefficient so that it is possible to disperse a dissolved contaminant into a medium. In addition, when the high-pressure fluid is changed into a supercritical fluid by bringing higher pressure thereon, it is possible to more penetrate even through fine patterns due to its property between gas and liquid. Further, density of the high-pressure fluid is close to that of liquid so that it is possible to contain a far larger amount of an additive (chemical agent) in comparison with gas.

The high-pressure fluid in the present invention is a fluid whose pressure is 1 MPa or more. The high-pressure fluid preferably used is a fluid which is known to possess high density, high solubility, low viscosity and high diffusion property, and further preferably used is a fluid which is in a supercritical or subcritical state. In order to bring carbon dioxide into a supercritical fluid, carbon dioxide may be at 31 degrees Celsius and of 7.1 MPa or more. It is preferable to use a subcritical fluid (high-pressure fluid) or supercritical fluid of 5 through 30 MPa at cleaning, and a rinsing step, a drying/developing step and the like after the cleaning, and it is further preferable to perform these processes under 7.1 through 30 MPa.

In case that a mixture of the high-processing fluid and the chemical agent is used as a processing fluid and that a solubility of the chemical agent functioning as a cleaning component in the high-pressure fluid is low, it is preferable to use a compatibilizer which can serve as an auxiliary agent dissolving or evenly diffusing the cleaning component in the high-pressure fluid. Especially, when the chemical agent contains humidity, solubility of the chemical agent in a supercritical fluid on carbon dioxide becomes extraordinary. Even if the solubility between the high-pressure fluid and the chemical agent including several components is low, addition of the compatibilizer makes the solubility be improved. This compatibilizer has a function that is for removing the chemical agent which remains onto the surface of the substrate in a rinse step after a cleaning step.

The above and further objects and novel features of the invention will more fully appear from the following detailed description when the same is read in connection with the accompanying drawing. It is to be expressly understood, however, that the drawing is for purpose of illustration only and is not intended as a definition of the limits of the invention.

### BRIEF DESCRIPTION OF THE DRAWINGS

FIG. 1 is a diagram showing an entire structure of a first embodiment of a high-pressure processing apparatus according to the present invention;

FIG. 2 is a view showing a pressure vessel and an inner structure thereof in the high-pressure processing apparatus shown in FIG. 1;

FIG. 3 is a top view of the pressure vessel taken from above along the line A-A′;

FIG. 4 is a sectional view of an upside member of the pressure vessel taken from the right direction;

FIGS. 5A and 5B are views schematically showing a processing fluid flow on the surface of the substrate;

FIG. 6 is a view showing a pressure vessel and an inner structure thereof in a second embodiment of a high-pressure processing apparatus according to the present invention;

FIG. 7 is a top view of the pressure vessel taken from above along the line B-B′;

FIG. 8 is a diagram showing an arrangement of pipes which deliver a processing fluid to the pressure vessel in the second embodiment;

FIG. 9 is a view of a pressure vessel which is equipped with a third embodiment of a high-pressure processing apparatus according to the present invention;

FIG. 10 is a view showing a fourth embodiment of a high-pressure processing apparatus according to the present invention;

FIG. 11 is a view showing a fifth embodiment of a high-pressure processing apparatus according to the present invention;

FIG. 12 is a view showing a sixth embodiment of a high-pressure processing apparatus according to the present invention;

FIG. 13 is a view showing a seventh embodiment of a high-pressure processing apparatus according to the present invention; and

FIG. 14 is a view showing an eighth embodiment of a high-pressure processing apparatus according to the present invention.

### DETAILED DESCRIPTION OF THE PREFERRED EMBODIMENTS

### First Embodiment

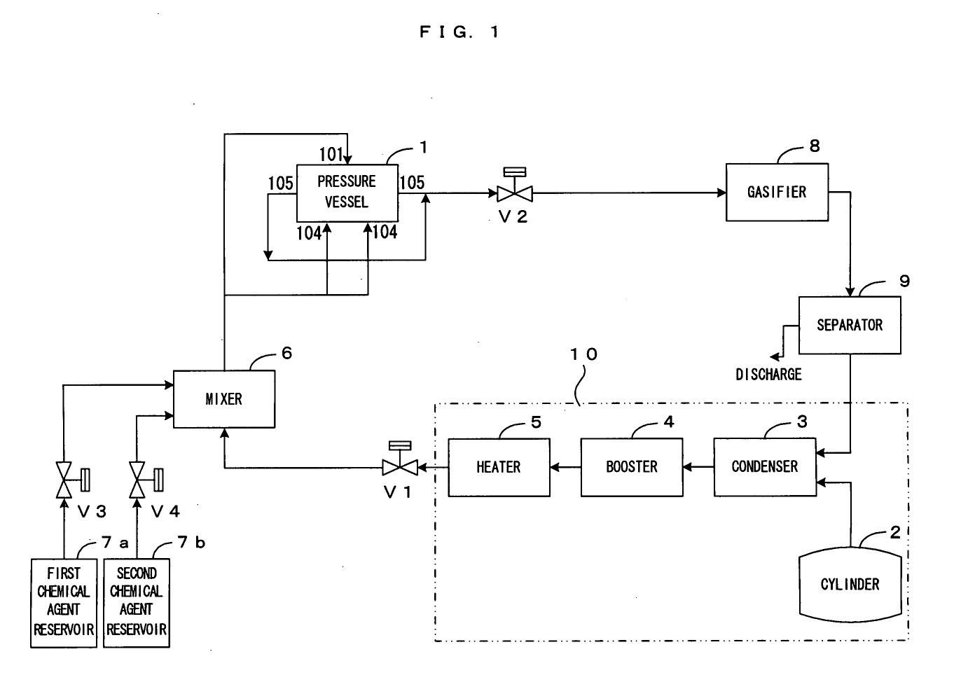

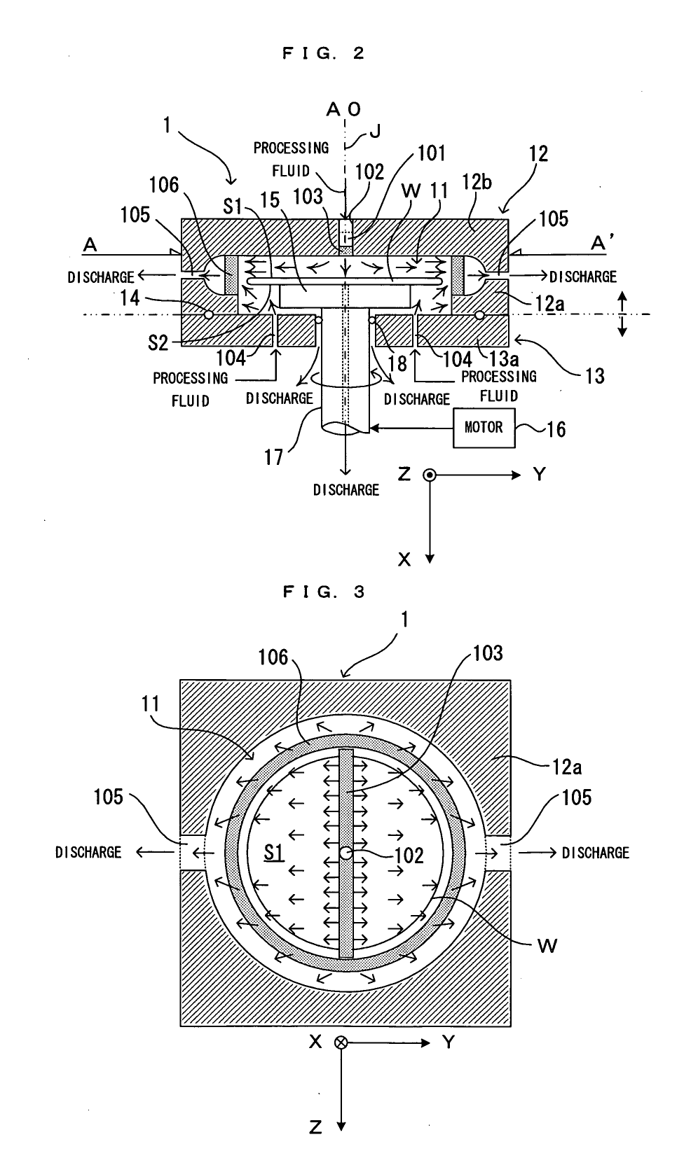

FIG. 1 is a diagram showing an entire structure of a first embodiment of a high-pressure processing apparatus according to the present invention. FIG. 2 is a view showing a pressure vessel and an inner structure thereof in the high-pressure processing apparatus shown in FIG. 1. FIG. 3 is a top view of the pressure vessel taken from above along the line A-A′. This high-pressure processing apparatus is an apparatus which introduces supercritical carbon dioxide (high-pressure fluid) or a mixture of supercritical carbon dioxide and a chemical agent, as a processing fluid, into a processing chamber 11 which is formed inside a pressure vessel 1, thereby performing predetermined cleaning and drying processes for a subround substrate (object-to-be-processed) W, such as a semiconductor wafer, which is held in the processing chamber 11. Hereinafter, structure and operation of the high-pressure processing apparatus will be described in detail.

In the high-pressure processing apparatus, while supercritical carbon dioxide is cyclically used, liquid carbon dioxide is supplied from a cylinder 2 when carbon dioxide inside the system decreases as the processing chamber 11 is opened to an atmospheric pressure or on other occasions. The cylinder 2 is connected with a condenser 3 or the like and reserves carbon dioxide as a liquid fluid under pressure of 5 through 6 MPa. The liquid carbon dioxide is pumped from the cylinder 2 by a pump (not shown), and supplied into the system through the condenser 3.

A booster 4 such as a pressure pump is connected to an output side of the condenser 3. High-pressure liquid carbon dioxide is obtained as liquid carbon dioxide is pressurized in the booster 4, and high-pressure liquid carbon dioxide is sent under pressure to a mixer 6 via a heater 5 and a high-pressure valve V1. High-pressure liquid carbon dioxide thus sent under pressure is heated by the heater 5 to a temperature which is suitable to a surface treatment (cleaning and drying), accordingly becomes supercritical carbon dioxide and is then sent to the mixer 6 via the high-pressure valve V1. Thus the cylinder 2, the condenser 3, the booster 4 and the heater 5 serve as a high-pressure fluid supplying unit 10 which supplies supercritical carbon dioxide as a high-pressure fluid.

Connected with the mixer 6 are two types of chemical agent reservoirs for storing and supplying chemical agents which are suitable for a surface treatment of the substrates W, namely, a first chemical agent reservoir 7a and a second chemical agent reservoir 7b respectively through high-pressure valves V3 and V4. Because of this, the high-pressure valves V3 and V4 are opened and closed under control, a first chemical agent from the first chemical agent reservoir 7a and a second chemical agent from the second chemical agent reservoir 7b are supplied, each in a quantity corresponding to the controlled opening and closing, to the mixer 6. Accordingly, the quantities of mixing the chemical agents with supercritical carbon dioxide are adjusted. Thus, according to this embodiment, it is possible to selectively prepare “supercritical carbon dioxide”, “supercritical carbon dioxide+first chemical agent”, “supercritical carbon dioxide+second chemical agent” and “supercritical carbon dioxide+first chemical agent+second chemical agent” as the processing fluid, and supply the same to the processing chamber 11 of the pressure vessel 1. The high-pressure fluid supplying unit 10 and the mixer 6 serve as a supplier or a supplying section. Furthermore, with a controller (not shown) appropriately controlling the high-pressure valves V3 and V4 to open and close in accordance with the contents of the surface treatment, it is possible to select the type of the processing fluid, and control densities of the chemical agents.

As shown in FIG. 2, the pressure vessel 1 comprises: a upside member 12 in which a side wall 12a and a ceiling wall 12b are integral with each other; and a downside member 13 which creates a bottom wall 13a. The upside member 12 and the downside member 13 are composed to bring into close contact through a seal 14 and are held each other. A cylindrical space is created inside the upside member 12, in which a substrate W can be set. The upside member 12 vertically moves while the downside member 13 standing still. Moving down comes the upside member 12 into contact with the downside member 13 whereas moving up departs the upside member 12 from the downside member 13. By doing this, the pressure vessel 1 can open and close freely. When the pressure vessel 1 is closed, the space inside the processing chamber 11 becomes air-tight stage. When the pressure vessel 1 is opened, an unprocessed substrate W is transferred onto a spin chuck 15 which is located inside the processing chamber 11 (Load of substrate W). Next to the load of the substrate, the pressure vessel 1 is closed and a surface treatment takes place. The surface treatment will be described later. Moreover, after the surface treatment is done, the pressure vessel is opened again and a processed substrate W is unloaded from the pressure vessel 1.

The spin chuck 15 is placed inside the processing chamber 11 and holds the substrate W in horizontal position for free rotations. That is, the spin chuck 15 functions as a “holder” of the present invention. Specifically, the spin chuck 15 has an upper surface onto which suction openings (not shown) are formed. A central portion of a bottom surface (second major surface) of the substrate W is drawn under suction generating at the suction openings while a surface thereof (first major surface) to be processed the surface treatment (high-pressure processing) facing up. By this suction operation, the spin chuck 15 holds the substrate W. The spin chuck 15 is jointly attached to a rotary shaft 17 which can be rotated by a motor 16 (rotating unit). On driving the motor 16, the spin chuck 15 as well as the substrate W is response to the rotation in an integrated fashion around a rotation axis J inside the processed chamber 11. A seal 18 is placed in a space between the rotary shaft 17 and a through hole provided at the bottom wall 13a of the pressure vessel 1. The seal 18 makes the processing chamber 11 to the air-tight stage against an outside atmosphere while holding the rotary shaft 17 so that the shaft 17 rotates free. The method of retaining the substrate W by means of the spin chuck 15 is not limited to suction. An arrangement for mechanically retaining the substrate is also possible.

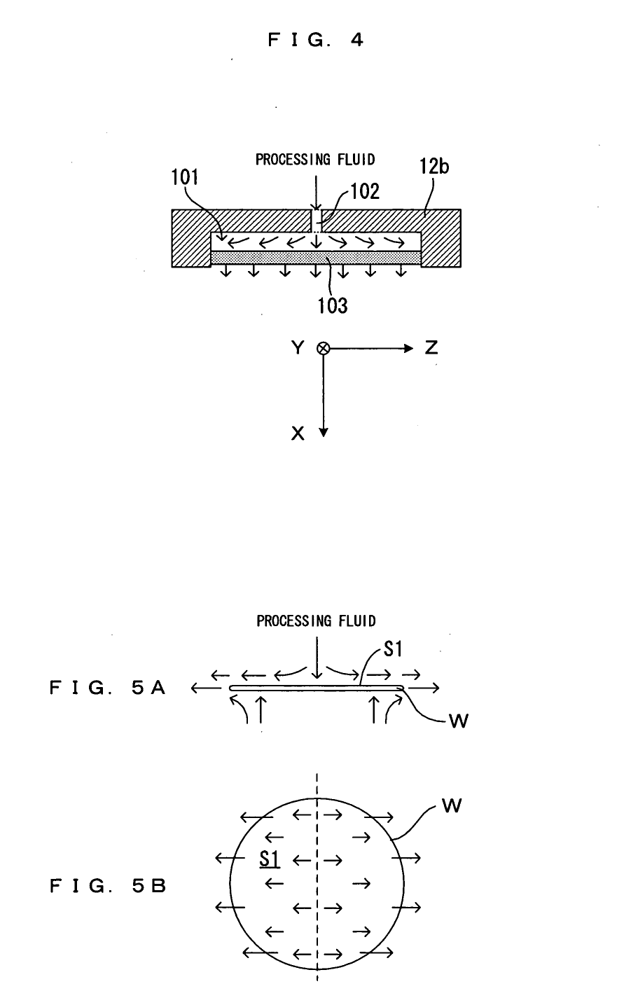

FIG. 4 is a sectional view of the upside member of the pressure vessel, shown in FIG. 2, taken from the right direction. A fluid delivery unit has a delivery path 101 and a fluid inlet port 102. The delivery path 101 is provided at an upper center portion of the pressure vessel 1 and a down side end of the delivery path 101 is opened toward the ceiling wall 12b of the pressure vessel I (upside member 12). The open end corresponding to an “opening” of the present invention. The opening of the delivery path 101 has a shape of a slit which elongates along a radial direction Z of the substrate W. The opening is positioned on a rotation center AO (approximately equal to the rotation axis J on the spin chuck 15) so as to face to the surface S1. The slit length along the radial direction Z is longer than a diameter of the substrate W. On the other hand, the slit width of the delivery path 101 along a direction Y perpendicular to the radial direction Z of the substrate W is less than 3 mm or the less than 1 mm is preferred. For example, a processing fluid may be blow off with an adequate fluid velocity to meet a cleaning process under 300 mm diameter substrate, when the delivery path 101 is formed with the slit length of over 300 mm and the width of under 1 mm.

A top central portion of the delivery path 101 is connected to the fluid inlet port 102 which is provided on the rotation axis J, so that the delivery path 101 and the mixer 6 is connected with each other through the fluid inlet port 102. Therefore, the processed fluid from the mixer 6 is send through the delivery path 101 to the processing chamber 11 and consequently delivered to the surface S1 of the substrate W.

A fluid dispersion member 103 (delivery side dispersion member) fits into the slit-like opening of the delivery path 101 at the lower edge side, that is, at the side of outlet for the processing chamber 11. The fluid dispersion member 103 is of a plate-like member in which many pores penetrate in a vertical direction X. As shown in FIG. 4, the processing fluid comes from the fluid inlet port 102 to the fluid dispersion member 103 and blows off from the delivery path 101 with uniform dispersion toward a longitudinal direction Z (to the horizontal direction in this figure). A punching metal board and a porous ceramics board may be used for the fluid dispersion member 103.

A downside inflow path 104 is provided to the bottom wall 13a of the pressure vessel 1. The processing fluid is delivered from the mixer 6 through the downside inflow path 104 into the processing chamber. The processing fluid from the downside inflow path 104 is supplied to a lower circumference portion of the substrate W, that is, an exposed portion on the lower surface S2 of the substrate W which is not held by the spin chuck 15. This substitutes a new processing fluid coming from the downside inflow path 104 for the processed fluid resident on the exposed portion, so as to prevent the residence of the processed fluid.

Lateral discharge paths 105 are provided to a lateral side of the pressure vessel 1. They are placed at the side walls 12a of the pressure vessel 1 (upper member 12), which face to an edge surface of the substrate W, so as to be positioned along the direction Y perpendicular to the longitudinal direction Z of the delivery path 101. Hence, they are formed as a pair. Specifically as shown in FIG. 3, a pair of discharge paths 105 is symmetrically created around the delivery path 101.

In addition, a fluid dispersion member 106 (discharge side dispersion member) is provided around the substrate W to the side walls 12a of the pressure vessel 1. The fluid dispersion member 106 is an annular disc member in which many pores penetrate in the radial direction to the substrate W. The processing fluid is delivered to the surface of the substrate W, and then flows out the both side of the substrate W. The runoff processing fluid blows off to the outside of the pressure vessel 1 through the fluid dispersion member 106 and the pair of lateral discharge path 105, 105. Therefore, this prevents from preferentially discharging the processing fluid existing at the edge portions of the substrate W which are the closest to the lateral discharge paths 105, 105. That is, it may be effectively prevented that short passes of the processing fluid flow occur. A punching metal board and a porous ceramics board may be used for the fluid dispersion member 106.

There may be a possibility of generating particles at the bottom wall 13a of the pressure vessel 1 because of the rotation of the rotary shaft 17. Therefore, in order to prevent the particle coming into the pressure vessel 1, the apparatus has an exhaust structure which exhausts air from a clearance between the rotary shaft 17 and the bottom wall 13a (inside wall of the hole provided in the bottom wall).

A gasifier 8 formed by a decompressor or the like is connected with the pair of the lateral discharge paths 105, 105. As a decompression process is executed, the fluid (processing fluid+contaminant and the like) discharged from the processing chamber 11 is delivered to the gasifier 8 through the lateral discharge paths 105, 105. The discharged fluid is completely gasified and fed to a separator 9. The separator 9 performs gas-liquid separation, thereby obtaining carbon dioxide as a gas component and a mixture of a contaminant and a chemical agent as a liquid component. At this moment, the contaminant may be precipitated as a solid and separated as it is mixed in the chemical agent. The separator 9 may be various types of apparatuses capable of performing gas-liquid separation, such as simple distillation, distillation (fraction) and flash separation, a centrifugal machine, etc.

Thus, this embodiment requires the gasifier 8 to completely gasify the fluid (processing fluid+contaminant and the like) discharged from the processing chamber 11 before the fluid is fed to the separator 9. This is for the purpose of improving efficiency of separation and efficiency of recycling carbon dioxide in the separator 9 because decompressed fluid such as carbon dioxide becomes a mixture of a gas-like fluid (carbonic acid gas) and a liquid-like fluid (deposit of the chemical agent dissolved in the supercritical carbon dioxide in the manner of the phase separation) in relation to a temperature.

The liquid (or solid) component comprised of a cleaning component or a compatibilizer which is separated in the separator 9 and contains a contaminant is discharged from the separator 9, and post-processed in accordance with necessity. On the other hand, carbon dioxide which is the gas component is supplied to the condenser 3 to be re-used.

Next a cleaning operation of the high-pressure processing apparatus as composed above will be described. Unwanted liquid and resist may stay on the surface of the substrate after an upstream process such as ashing and dry etching is completed. Therefore, after the completion of the upstream process, the high-pressure processing apparatus performs a cleaning process (cleaning step and rinsing step) upon the receipt of the substrate W as follow. An unprocessed substrate W is delivered to the opened pressure vessel 1 and is placed on the spin chuck 15 so that the surface S1, onto which the surface treatment (high-pressure processing) is objected, faces upward. Then the substrate W is absorbed and held to the spin chuck 15 and thereafter the pressure vessel 1 is closed.

In the cleaning step, the booster 4 pressures liquefied carbon dioxide to form high-pressure liquefied carbon dioxide and then the heater 5 heats the high-pressure liquefied carbon dioxide to form supercritical carbon dioxide. On opening the high-pressure valve V1, the supercritical carbon dioxide is delivered to the mixer 6. Further, the high-pressure valve V3 is opened to place the first chemical agent reservoir 7a in supply mode, whereby the first chemical agent is supplied from the first chemical agent reservoir 7a to the mixer 6. As a result, the first chemical agent is mixed together with the supercritical carbon dioxide and consequently the processing fluid suitable for the cleaning processing is prepared. The first chemical agent may be an agent such as tertiary amine or fluoride which has a cleaning effect. As more specific examples, there are quaternary ammonium fluoride, alkylamine, alkanolamine including monoethanolamine, hydroxylamine (NH₂OH) or ammonium floride (NH₄F). Contents of cleaning components can be adjusted for the required effect.

As the above mentioned cleaning components are not easy to melt into the high-pressure fluid, it is preferred to add compatibilizer which can be an auxiliary agent to make the cleaning component deliquescent or homogeneous dispersion in the carbon dioxide. As for the compatibilizer, there is no limitation as long as it can compatibilize the cleaning component or unwanted material into the high-pressure fluid. Those can be alcohol including methanol, ethanol, isopropanol and the like, and alkyl sulfoxide including dimethyl sulfoxide.

The processing fluid regulated at the mixer 6 is delivered into the processing chamber 11 through the delivery path 101 provided on the pressure vessel 1 and is blown off onto the surface S1 of the substrate W which is held by the spin chuck 15. Also the processing fluid is supplied from the downside inflow path 104 into the processing chamber 11, so as to be supplied to the lower edge portion of the substrate W. At the same time or before and after with the supply of the processing fluid, a motor 16 is driven to rotate the substrate W.

FIGS. 5A and 5B are views schematically showing a processing fluid flow on the surface of the substrate. The processing fluid from the delivery path 101 is in a shape of a curtain with a width longer than a diameter of the substrate W along the direction Z, and incident vertically into the surface S1 of the substrate W along the rotation center AO of the substrate W. As a result, the processing fluid touches the surface S1 of the substrate W, whereby a predetermined cleaning process is performed. Keeping the symmetry on the both sides of the substrate W, the processing fluid supplied onto the surface S1 of the substrate flows horizontally on the substrate S1 and then is discharged from both of discharge paths 105, 105. From the view of the flow direction of the processing fluid on the surface S1 as well as the rotation motion of the substrate W, inplane uniformity of the processing fluid can be kept. Therefore it is prevented that the processing fluid supplied to the surface S1 stays on the surface in an undesirable manner.

The curtain of the processing fluid is vertically incident into the rotating substrate W one after another, whereby the predetermined cleaning process for the whole surface S1 of the substrate is performed by the processing fluid.

By this cleaning process, a contaminant attached to the substrate W is deliquescent into the processing fluid (supercritical carbon dioxide+the first chemical agent) inside the processing chamber 11. At this stage, if the first chemical agent is consist of the cleaning component and the compatibilizer, a rinsing process is preferred to have the two rinse steps. The contaminant is deliquescent into the supercritical carbon dioxide by the effect of the cleaning component and the compatibilizer component. If only supercritical carbon dioxide is distributed inside the processing chamber 11 for the single cleaning step, there is a possibility that deliquescent contaminant deposit on the surface of the substrate. Therefore the first rinse step with the supercritical carbon dioxide and the compatibilizer and the second rinse steps with only with supercritical carbon dioxide are preferred as this order.

In this embodiment, after a predetermined processing time has passed from the beginning of the cleaning step, that is, the beginning of supply of the first chemical agent, the high-pressure value V3 is closed. In other words, the first chemical agent reservoir 7a is placed in supply stop mode to stop the first chemical agent (cleaning component) being pressure-fed from the first chemical agent supply reservoir 7A to the mixer 6. Whereas, the high-pressure valve V4 is opened to start the second chemical agent (compatibilizer) being pressure-fed from the second chemical agent reservoir 7b. Thus, by opening and closing control of the high-pressure valves, the supercritical carbon dioxide and the compatibilizer are mixed at the mixer 6, whereby the first rinse processing fluid is regulated and supplied to the processing chamber 11. On distributing this first rinse processing fluid within the processing chamber 11, the cleaning component and contaminant gradually reduce. Finally it is filled with the first rinse processing fluid (supercritical carbon dioxide+compatibilizer). As for the compatibilizer, the same add-in material can be used for the first chemical agent or the different one can be used.

In this way, when the first rinse step is completed, the second rinse step takes place. In the second rinse step, the high-pressure value V4 is closed to place the second chemical agent reservoir 7b in supply stop mode, so as to stop the second chemical agent (compatibilizer component) being pressure-fed from the second chemical agent supply reservoir 7B to the mixer 6. As a result, only supercritical carbon dioxide is supplied as the second rinse processing fluid to the processing chamber 11. The processing chamber 11 is filled with second rinse processing fluid (supercritical carbon dioxide) by distribution the second rinse processing fluid within the processing chamber 11.

The high-pressure valve 2 is always open mode all the way during the cleaning steps, the first rinse step and the second rinse step. To be more specific, the controller monitors an inside pressure of the processing chamber 11 and adjusts the opening of the valves so as to keep the monitoring result constant. Therefore, the inside pressure of the processing chamber 11 is controlled.

At a next step, the high-pressure valve V1 is closed to reduce the pressure. When the inside pressure of the processing chamber 11 returns into an atmospheric pressure, the pressure vessel 1 is opened and the processed substrate W is unloaded. Hence, all succeeding process (cleaning process and rinsing process) will be completed. When a subsequent substrate yet to be processed is transported, the operation above is repeated.

As described above, according to this embodiment, the curtain of the processing fluid, having the width of more than the diameter of the substrate W, is supplied along the rotation center AO of the substrate W and is incidence vertically into the surface S1 of the rotating substrate W. Thus the processing fluid, which is incidence vertically onto the surface S1, is cleaning the whole surface S1 and the processing time is shortened by this. The opening of the delivery path 101 is shaped in a slit while an area of the opening is small in relation to the whole surface area of the surface S1. This makes a flow velocity of the processing fluid high than that in the conventional technology. As a result, efficiency of the processing speed per unit area is increased. Furthermore, since the opening shape of the delivery path 101 is limited to be in a slit, work accuracy becomes higher due to easily form the delivery path 101 onto the wall of pressure vessel 1. Therefore, the flow velocity of the processing fluid coming into the surface S1 vertically is kept be uniformed. As a result, by rotating the substrate W, the whole of the surface S1 can be uniformly processed.

Further, the fluid dispersion member 103 is fitted into the delivery path 101 and prevents the processing fluid from deviating within the opening surface of the delivery path 101. This allows that the curtain of the processing fluid is provided with uniformity along the radial direction of the substrate W.

Further, according to the embodiment, the pair of discharge paths 105, 105 is provided onto side walls 12a of the pressure vessel 1 so as to face each other along the direction Y perpendicular to the longitudinal direction X of the delivery path 101. Therefore the processing fluid supplied onto the surface S1 is discharged laterally out of the substrate W while keeping the symmetry on the both sides of the substrate W. This prevents the processing fluid from accumulating onto the surface S1 of the substrate W.

In addition, as the fluid dispersion member 106 is provided around the substrate W, the residence of the processing fluid onto the surface S1 is prevented. This allows that the surface S1 is processed with better inplane uniformity while the processing fluid is discharged.

### Second Embodiment

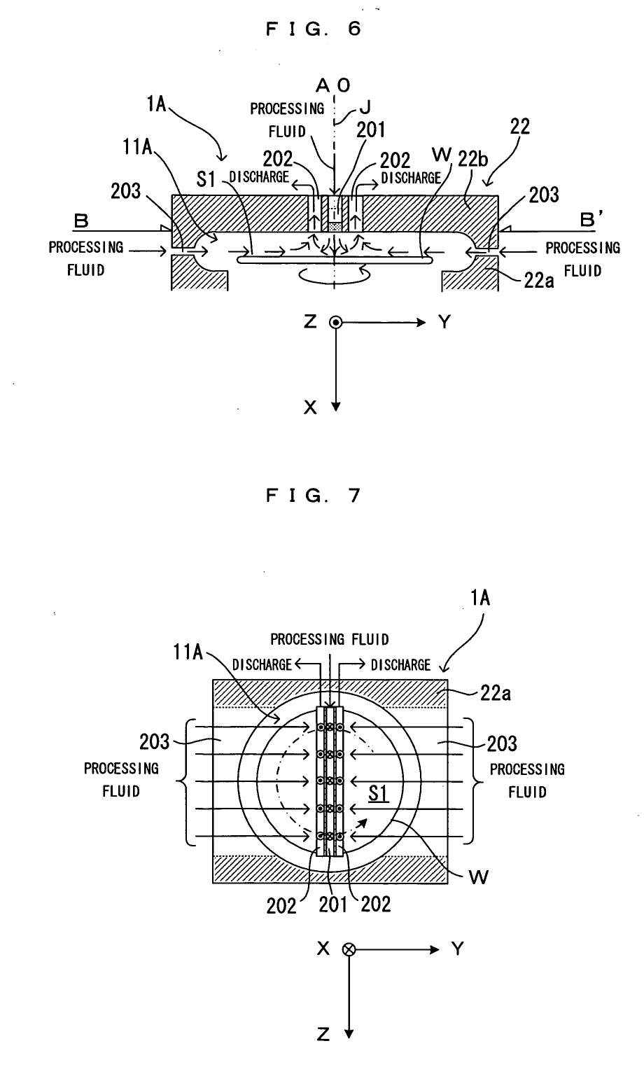

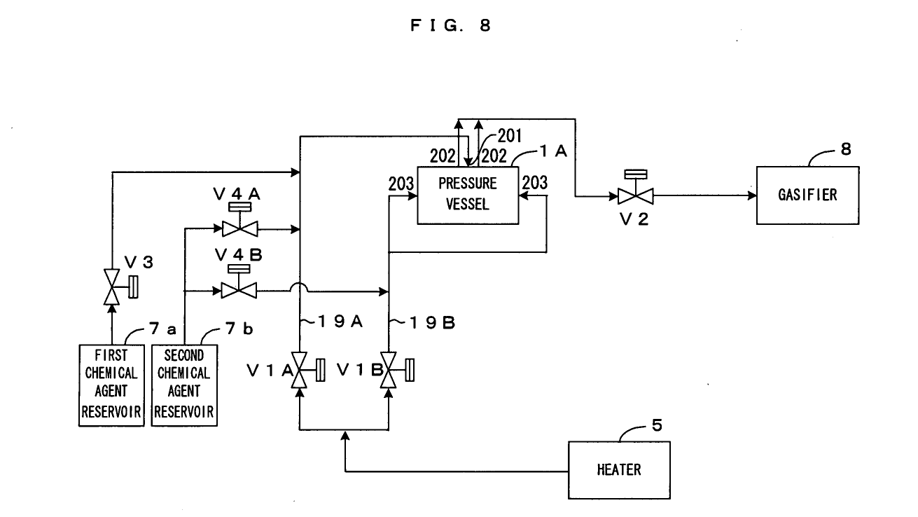

FIG. 6 is a view showing a pressure vessel and an inner structure thereof in a second embodiment of a high-pressure processing apparatus according to the present invention. FIG. 7 is a top view of the pressure vessel taken from above along the line B-B′. FIG. 8 is a diagram showing an arrangement of pipes which deliver a processing fluid to the pressure vessel in the second embodiment. This second embodiment has the common with the first embodiment in a specific structure in which a processing fluid is fed toward a surface S1 of a substrate W from a slit delivery path 201 elongating along a direction Z. However a large difference are the way of discharging the processing fluid and the way of supplying the processing fluid additionally from edge sides of the substrate W. Hereinafter, the point of difference in the structure and the operation between the first embodiment and the second embodiment will be described.

In this second embodiment, there are three opening slits onto a ceiling wall 22b of a pressure vessel 1A side by side along a direction Y. The slits face to the surface S1 of the substrate and elongate along the direction Z. Among those, a delivery path 201 is opened toward the radial direction of the substrate W so that an opening of the delivery path 201 is positioned on the rotation center AO of the substrate W. The slit length of the delivery path 201 is longer than a diameter of the substrate W. A pair of discharge paths 202, 202 is provided both sides of the delivery path 201 along the longitudinal direction Z of the delivery path 201 so as to sandwich the delivery path 201.

Lateral inflow units 203 are provided to a side wall 22a of the pressure vessel 1A to bring the processing fluid into the processing chamber 11A. The lateral inflow units 203 supply the processing fluid from the both sides of the substrate W to the surface S1. Specifically, the processing fluid is supplied from the both sides of the substrate W along the direction Y perpendicular to the longitudinal direction Z of the delivery path 202. Thus supplied processing fluid flows onto the surface S1 of the substrate over the diameter of the substrate W. According to the second embodiment, as a processing fluid, only supercritical carbon dioxide is supplied from the lateral inflow units 203.

In this high-pressure processing apparatus, a pipe for pressure feeding of the processing fluid to the processing chamber 11A is branched at a downstream side from the heater 5. One branch pipe 19A is connected to the delivery path 201 through a high-pressure valve V1A while another branch pipe 19B is connected to the lateral inflow units 203 through a high-pressure valve V1B. The first chemical agent reservoir 7a is connected through the high-pressure valve V3 to the branch pipe 19A. Furthermore, the second chemical agent reservoir 7b is connected through the high-pressure valve V4A to the branch pipe 19A. The pair of discharge paths 202, 202 is connected to the decomposer or gasifier 8 via a high-pressure valve V2. The fluid (processing fluid+contaminant) is discharged from the processing chamber 11A through the pair of discharge paths 202, 202 which are connected to the gasifier 8 via the high-pressure valve V2. The structures in an upstream from the heater 5 and in a downstream from the gasifier 8 are the same as the first embodiment and therefore the description thereof will be eliminated.

In the high-pressure processing apparatus, the high-pressure valves V1A, V1B, V3 open to execute the cleaning step. The opening of the valves make the processing fluid (mixture of the supercritical carbon dioxide, the cleaning component and the compatibilizer as additive) be supplied through the delivery path 201 and vertically incident to the surface S1 of the rotation substrate W. At the same time, the processing fluid including only the supercritical carbon dioxide is supplied from the lateral inflow units 203. Also at the same time, the high-pressure valve V2 is opened to discharge the processing fluid (processed fluid) toward the upper side of the surface S1 through the lateral discharge paths 202, 202 which are disposed to the both sides of the delivery path 201. The processing fluid including only the supercritical carbon dioxide, which inflows from the lateral inflow units 203, is supplied to the surface S1. This prevents from flowing the processing fluid toward the side walls 22a of the pressure vessel 1A. In this embodiment as well as the first embodiment, the controller adjusts the opening of the high-pressure valve V2 so as to keep the monitoring result constant.

After the completion of the predetermined cleaning step, a first rinse step is taken place. At the first rinsing process, the high-pressure valves V1A, V1B, B4A and V2 are opened meanwhile the high-pressure valves V3 and V4B are closed. As a result, the processing fluid (mixture of the supercritical carbon dioxide and the compabitilizer) is supplied to the processing chamber 11 through the delivery path 201 while the processing fluid including only the supercritical carbon dioxide is supplied from the lateral inflow units 203. In order to increase the rinse effect under the first rise step, the high-pressure valve V4 may be opened so as to supply the processing fluid from the lateral inflow units 203 as same as from the delivery path 201.

Specifically, in case that the cleaning component from the delivery path 201 remains on the surface S1 of the substrate, the mixture containing the supercritical carbon dioxide and the compatibilizer may be supplied to the surface S1 from the lateral inflow units 203. The supplied mixture rinses away the cleaning component which remains on the surface S1 with accelerating speed.

After the completion of the first rinse step, the second rinse step is continuously performed. At the second rinse step, the high-pressure valves, V3, V4A and V4B are closed meanwhile the high-pressure valves V1A, V1B and V2 are opened. As a result, the processing fluid including only supercritical carbon dioxide is introduced through the lateral inflow units 203 and the delivery path 201 as well as discharged on the upper side of the surface S1 from the pair of discharge paths 202.

Next to this, the high-pressure valves V1A and V1B are closed to decrease the inner pressure. This makes the inside of the processing chamber 11A at atomasphic pressure. Thereafter, the processed substrate W is unloaded from the opened pressure vessel 1A.

As described above, according to the embodiment, the curtain of the processing fluid having the width longer than the diameter of the substrate W is incident vertically to the surface S1 of the rotating substrate W. This may obtain the same effect as the first embodiment.

According to the embodiment, the pair of discharge paths 202, 202 is provided around the delivery path 201 so as to sandwich the delivery path 201, whereby the processing fluid is discharged immediately toward the upper side of the surface S1 through the discharge paths 202, 202. This prevents from remaining the processing fluid (processed fluid) onto the surface S1 of the substrate. In addition, because of the supply of the processing fluid from the lateral inflow units 203 to the both side of the substrate W, the processed fluid is not flown toward the both side of the substrate W but is discharged from a pair of the discharge path 202, 202 for sure.

According to the embodiment, the processing fluid includes the cleaning component is supplied through the delivery path 201 to the surface S1. Therefore, the processing fluid contribute to a chemical reaction (processing reaction with the cleaning component) is restricted to the processing fluid with a high-reaction rate, that is, the processing fluid which is incident vertically to the surface S1. As a result, this raises the merit of using the cleaning component.

At the cleaning step of the second embodiment, the processing fluid including the supercritical carbon dioxide only is introduced from the lateral inflow units 203. The compatibilizer may be mixed into the supercritical carbon dioxide by opening the high-pressure valve V4B to prepare as the processing fluid through the lateral inflow units 203 at the cleaning step.

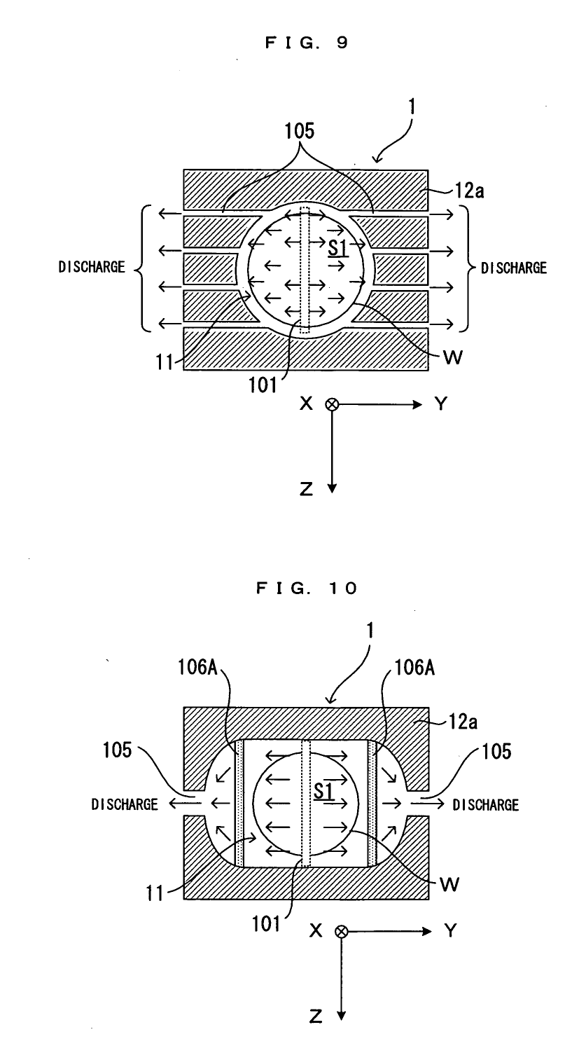

The present invention is not limited to the embodiments described above, but may be modified in various fashions other than those described above to the extent not deviating from the purpose of the invention. For instance, in the first embodiment, the fluid dispersion member 106 is placed around the substrate W so that the processing fluid is discharged with a good inplane uniformity with respect to the surface S1. The way of discharge is not limited to this way. For example, as shown in FIG. 9, several pairs of lateral discharge paths 105, 105 may be provided on the side wall 12a of the pressure vessel 1 along the longitudinal direction Z of the delivery path 101 (third embodiment). The apparatus having the structure gets the same effect which can be obtained as setting the fluid dispersion member 106.

Further the discharge direction of the processing fluid is optional. For example, as shown in FIG. 10, it is capable that many lateral discharge paths may be grouped together to a lateral discharge path 105 on the side walls 12a. That is, in this embodiment, fluid dispersion members 106A, 106A having the same length are provided in a parallel to the longitudinal direction Z of the delivery path 101. Also the fluid dispersion members 106A, 106A may be disposed corresponding to the lateral discharge paths 105, 105, respectively (fourth embodiment).

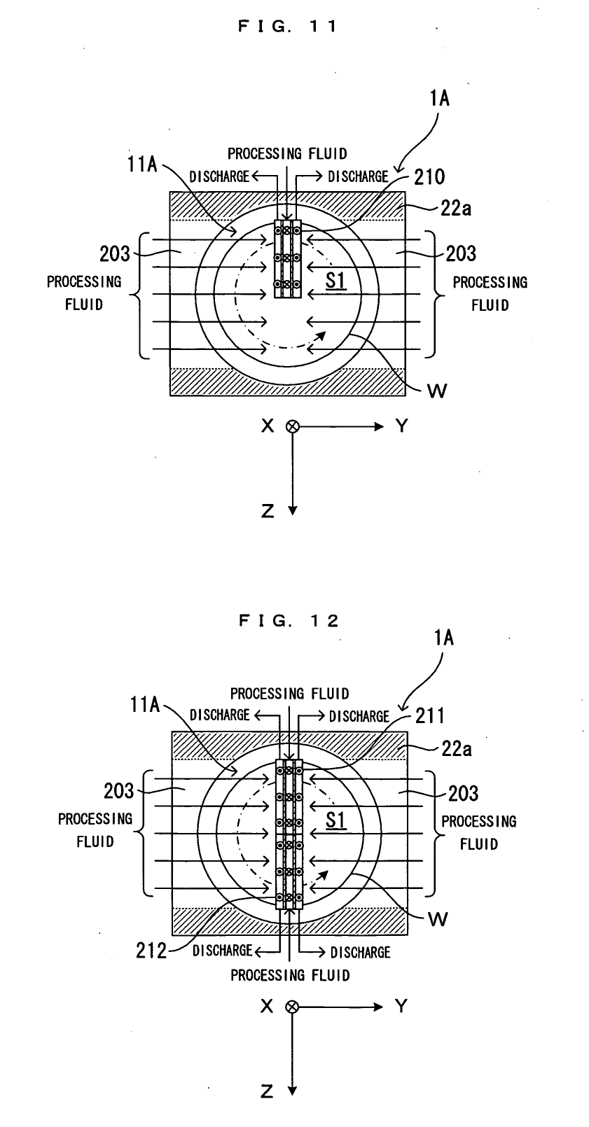

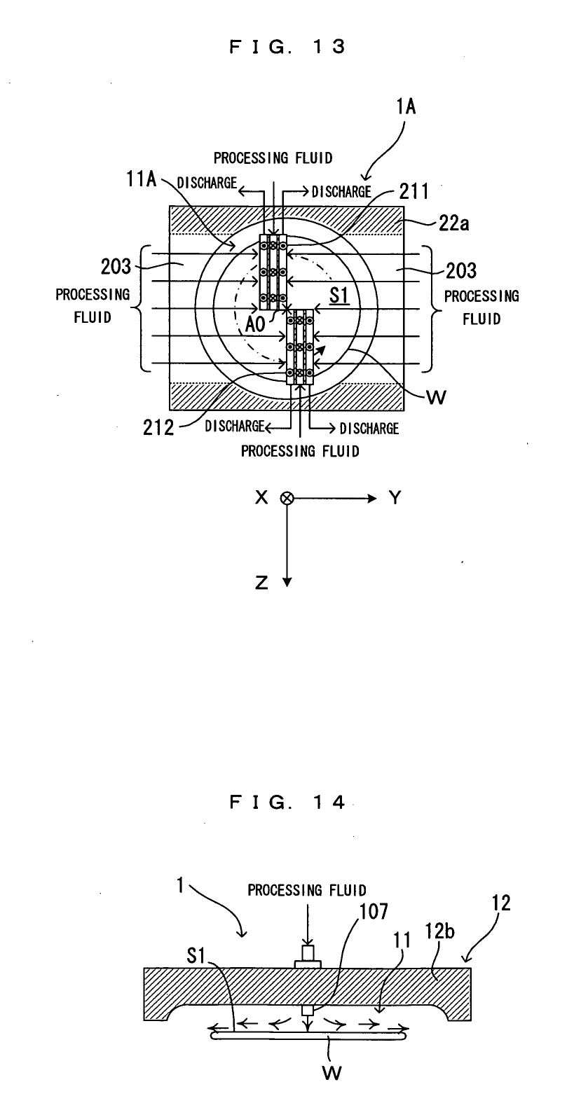

In the second embodiment, a pair of discharge paths 202, 202 which sandwiches the delivery path 201 as well as the delivery path 201 has the slit length longer than the diameter of the substrate W. Hereinafter the paths 201, 202, 202 are collectively referred as “delivery and discharge group”. It is not limited to this. As shown FIG. 11, a slit length of the delivery and discharge group 210 may be identical with the radius of the substrate W (fifth embodiment). Like this, when the slit length of the delivery and discharge group 210 is set to the radius of the substrate W, a work accuracy of the delivery path 201 becomes better. This makes the flow velocity of the processing fluid coming from the delivery path 201 equalized. Further, by reducing the opening area of the delivery path 201, the flow velocity of the processing fluid becomes faster. This makes processing efficiency per dimension increase. In the first embodiment, there may be a case where the process comes under the large influence of the processing fluid which flows in parallel along the surface S1 of the substrate to reach the lateral discharge path 105. In this case, the slit length of the delivery path 101 can be as same as the radius of the substrate W.

Also, if the slit length of the delivery and discharge group is set as the radius of the substrate W, a plurality of lateral inflow units can be provided. For example, as shown in FIG. 12, two delivery and discharge groups 211, 212 may be provided on a line along the longitudinal direction Z thereof while being in a parallel to the radial direction of the substrate W (sixth embodiment). In the apparatus having the structure above, several surface processing becomes possible onto the substrate W and the flexibility of the apparatus becomes higher. For example, with one unit 211 a mixture of the supercritical carbon dioxide and the cleaning component may be supplied and discharged as one processing fluid while with the other unit 212 a mixture of the supercritical carbon dioxide and the compatibilizer may be supplied and discharged as the other processing fluid. Further, with one unit 211 a mixture of the supercritical carbon dioxide and the compatibilizer may be supplied and discharged as one processing fluid while with the other unit 212 only supercritical carbon dioxide may be supplied and discharged as the other processing fluid.

Further, the arrangement of the delivery and discharge group 211, 212 may be not only a line layout where the units are on a line along the longitudinal direction Z thereof, but may be an alternative layout where the units are symmetric with the rotation center AO of the substrate W and alternatively disposed in a direction perpendicular to the longitudinal direction Z of the delivery and discharge groups (seventh embodiment). Hence, in the apparatus equipped with a plurality of delivery and discharge groups, design flexibility of process can be increased dramatically.

Although two types of chemical agents are mixed into the supercritical carbon dioxide (high-pressure fluid) to prepare the processing fluid in the embodiments above, the kinds and the number of chemical agents may be freely determined. When the surface treatment is performed not using any chemical agents, the chemical agent reservoirs become unnecessary.

Although the cleaning process is conducted as the surface treatment in the embodiments described above, the applicable object of the present invention is not limited to the apparatus described above. For example, the present invention can be applied to an apparatus which executes a surface treatment (such as developing process) and an apparatus which executes a drying processing on receiving the substrate with the developing, cleaning and rinsing process. In this case, after the completion of a wet processing, the curtain of the processing fluid (supercritical carbon dioxide) is vertically incident to the surface S1 of the rotation substrate W, whereby the process is speeding up and the drying process is effectively performed.

In the embodiments described above, one major surface S1 within the both major surfaces of the substrate W which faces upward, corresponds to the “surface” of the present invention and the predetermined surface treatment is performed to the surface S1. When the surface treatment is performed to the other surface S2 of the substrate W, the substrate W may be held while the surface S2 facing upward. Further if there is a need to make both surfaces be performed the surface treatment, the slit type openings may be formed to face toward the both major surfaces S1 and S2. The both edges of the substrate W is to be hold mechanically when the surface treatment is taken place to the other major surface S2 or the both major surfaces.

Although the description has been given to the case of processing to the subround shape substrate W as “object-to-be processed”, the shape of the substrate W is not limited to this. For example, the surface treatment can be performed to a square surface. In the case “fluid delivery unit” may have a slit type opening elongating along a radial direction of the substrate while having a slit length longer than a distance from the rotation center of the substrate W to the edge of the substrate W along the radial direction of the substrate W. The apparatus having the structure above may obtains some effects as same as the above embodiment.

Although the heater 5 is set primary side from the mixer 6 in the figure, another heater can be added between the pressure vessel 1 and the mixer 6. For example, the additional heater is very effective for a specific apparatus in which a length from the mixer 6 to the pressure vessel is too long and it is hard to keep the processing temperature when reaching the processing chamber 11.

The present invention can be applied to the high-pressure apparatus which conducts the surface treatment (developing, cleaning and drying process) to the object-to-be-processed such as a semiconductor wafer, a glass substrate for liquid crystal display, a substrate for PDP (=Plasma Display Panel), a glass substrate or a ceramic substrate for disc unit, with using the processing fluid that is made of the high pressure fluid or the mixture of the high pressure fluid and the chemical agent.

Although the invention has been described with reference to specific embodiments, this description is not meant to be construed in a limiting sense. Various modifications of the disclosed embodiment, as well as other embodiments of the present invention, will become apparent to persons skilled in the art upon reference to the description of the invention. It is therefore contemplated that the appended claims will cover any such modifications or embodiments as fall within the true scope of the invention.

What is claimed is:

1. A high-pressure processing apparatus which causes a high-pressure fluid or a mixture of a high-pressure fluid and a chemical agent, as a processing fluid, to come into contact with a surface of an object-to-be-processed, thereby performing a predetermined surface treatment for the surface of the object-to-be-processed, the high-pressure processing apparatus comprising:
a supplier which supplies the processing fluid;
a pressure vessel which has a processing chamber therein for performing the surface treatment;
a holder which holds the object-to-be-processed inside the processing chamber;
a rotating unit which rotates the object-to-be-processed held by the holder;
a fluid delivery unit which has an opening and delivers the processing fluid, supplied from the supplier, vertically toward the object-to-be-processed of the substrate through the opening, so as to supply the processing fluid onto the surface of the object-to-be-processed, the opening being positioned on a rotation center of the object-to-be-processed and facing the surface of the object-to-be-processed; and
a fluid discharge unit which discharges the processing fluid, supplied from the fluid delivery unit onto the surface of the object-to-be-processed, out of the pressure vessel,
wherein the opening has a shape of a slit which elongates along a radial direction of the object-to-be-processed and has a slit length longer than a distance from the rotation center of the object-to-be-processed to an edge of the object-to-be-processed along the radial direction of the object-to-be-processed.

2. The substrate processing apparatus of claim 1, wherein
the object-to-be-processed is a subround substrate, and
the fluid delivery unit has a delivery path having a shape of a slit and elongating along the radial direction of the substrate and introduces the processing fluid through the delivery path into the processing chamber so as to delivery the processing fluid, the delivery path being provide on a wall of the pressure vessel, which faces to the surface of the substrate, and having a slit length which is longer than a radius of the substrate.

3. The substrate processing apparatus of claim 2, wherein the fluid delivery unit has a delivery side dispersion member, disposed into the delivery path, which disperses the processing fluid in the radial direction of the substrate as well as delivers the dispersed processing fluid.

4. The substrate processing apparatus of claim 2, wherein the delivery path has the slit length which is longer than a diameter of the substrate.

5. The substrate processing apparatus of claim 4, wherein the fluid discharge unit has a pair of lateral discharge paths and discharges the processing fluid, supplied onto the surface of the substrate, through the lateral discharge paths out of the pressure vessel, the lateral discharge paths being respectively disposed onto both side walls of the pressure vessel along a direction perpendicular to a longitudinal direction of the delivery path so as to face to edge portions of the substrate.

6. The substrate processing apparatus of claim 5, wherein the fluid discharge unit has a discharge side dispersion member, placed around the substrate, which disperses the processing fluid, flowing out of the substrate, in a circumferential direction of the substrate as well as discharges the dispersed processing fluid through the lateral discharge paths.

7. The substrate processing apparatus of claim 5, wherein the fluid discharge unit has the plurality of lateral discharge path pairs which are disposed along the longitudinal direction of the delivery path.

8. The substrate processing apparatus of claim 2, wherein the fluid discharge unit has a pair of discharge paths and discharges the processing fluid, supplied onto the surface of the substrate, through the pair of discharge paths out of the pressure vessel, the pair of discharge paths facing to the surface of the substrate and being adjacent to both side of the delivery path so as to sandwich the delivery path.

9. The substrate processing apparatus of claim 8, further comprising a lateral inflow unit which introduces the processing fluid into the processing chamber to supply from both side of the substrate onto the surface of the substrate in a direction perpendicular to a longitudinal direction of the delivery path.

10. The substrate processing apparatus of claim 8, wherein
the fluid delivery unit has the plurality of delivery paths and the fluid discharge unit has the plurality of discharge path pairs, and
a plurality of delivery and discharge groups, each of which has the delivery path and the pair of discharge paths sandwiching the delivery path, are provided.
